(19) United States
(12) Patent Application Publication
(10) Pub. No.: US 2006/0110868 A1
(43) Pub. Date: May 25, 2006

(54) Production of lightly doped drain of low-temperature poly-silicon thin film transistor

(75) Inventors: Chia-Nan Shen, Padeh City (TW); Cheng-Nan Hsieh, Padeh City (TW); Po-Chih Liu, Padeh City (TW)

Correspondence Address: BACON & THOMAS, PLLC, 625 SLATERS LANE, FOURTH FLOOR, ALEXANDRIA, VA, 22314, US

(73) Assignee: ChungHwa Picture Tubes., LTD, Padeh City (TW)

(21) Appl. No.: 11/023,436

(22) Filed: Dec. 29, 2004

(30) Foreign Application Priority Data
Nov. 25, 2004 (TW) 093136377

(51) Int. Cl. H01L 21/84

(52) U.S. Cl. 438/163; 438/166; 438/486

(57) ABSTRACT

A method is disclosed to make a lightly doped drain of a low-temperature poly-silicon thin film transistor. Nitrogen is implanted during steps of doping the source and the drain so as to suppress the spreading of the other types of dope so that the poly-silicon layer forms a shallow interface lightly doped drain after annealing. Implantation of nitrogen takes place before or after the other types of dope. Nitrogen is implanted to a depth no greater than that of the other types of dope. The present is simple, improves hot carrier effect and repairs flaws in the poly-silicon layer.

### BACKGROUND OF THE INVENTION

1. Field of the Invention

The present invention relates to the production of a low-temperature poly-silicon thin film transistor via and, more particularly, to a method for producing a lightly doped drain of a low-temperature poly-crystal thin film transistor and a method for doping the same.

2. Description of the Related Art

A thin film transistor (“TFT”) is an essential element for controlling the brightness of a pixel of a liquid crystal display. As technology develops, poly-silicon structures can be formed via laser annealing processes at low temperatures. Thin film transistors have evolved from amorphous structures to low-temperature poly-silicon (“LTPS”) structures. This evolution magnificently improves the electric properties of thin film transistors, and renders possible direct forming of a TFT on a glass substrate that cannot stand high temperatures.

Problems have however been encountered in using LTPS. Take a P-type silicon substrate for example. A conventional typical LTPS-TFT includes, on a poly-silicon layer two n-type heavily doped areas as the source and the drain. Because of the high concentration of the dope in the source and the drain and because of the small distances of the source and the drain from the gate, a strong electric field occurs near the drain and entails a hot carrier effect. Hence, the LTPS-TFT, when turned off, suffers leakage current that severely degrades the stability thereof. To contain this problem, lightly doped drain (“LDD”) structures have been developed in order to reduce leakage current via reducing the electric field at the interface of the drain.

As shown in FIG. 1a and 1b, there is shown a conventional method for making a conventional LTPS-TFT with an LDD structure. Referring to FIG. 1a, on a transparent substrate 10 is formed a poly-silicon layer 12 and a gate insulator 14 covered on the poly-silicon layer 12. A photo-resistance layer 16 is defined and formed on the gate insulator 14. With the photo-resistance layer 16 used as a mask, a heavy ionic dope-implanting operation 19 is taken so as to form a heavily doped area 18 as a source/drain area on the poly-silicon layer 12 around the photo-resistance layer 16. Referring to FIG. 1b, after the photo-resistance layer 16 is removed by etching, a gate 20 is formed on the gate insulator 14 so as to cover a portion of a non-doped area on the poly-silicon layer 12. Then, with the gate 20 used as a mask, another ionic dope-implanting operation 21 is taken so as to form, in a non-doped area around the gate 20, a lightly doped area 22 as an LDD structure. The portion of the poly-silicon layer 12 covered by means of the gate 20 is used as a channel.

Although an LDD structure is formed in the above-mentioned method so as to suppress the hot carrier effect caused by the short channel, many steps have to be taken for photo-resistance coating and development. Additional masks are needed to define the photo-resistance layer 16. Since alignment bias can easily be generated in exposure, the LDD structure can easily be shifted. Even if a source/drain pattern is defined by means of self-alignment beforehand so as to avoid such errors, the development will remain dispensable. Moreover, regarding a p-n-p type PMOS, abnormal spreading can easily occur during the tail in high-temperature annealing because the p-type conductor is substantially made of boron that includes small atoms and is light in weight. It is difficult to control the depth of the p-n interface and the dope concentration therein. The stability of the resultant transistor is affected.

Therefore, the present invention is intended to obviate or at least alleviate the problems encountered in prior art.

### SUMMARY OF THE INVENTION

It is the primary objective of the present invention to provide a method for-producing a lightly doped drain of a low-temperature poly-silicon thin film transistor while reducing steps related to photo-resistance coating and development and eliminating leakage current because of hot carrier effect and can repair flaws in the poly-silicon layer.

According to the present invention, a method for producing a lightly doped drain of a low-temperature poly-crystal thin film transistor, the method comprising steps of: providing a transparent substrate; forming a poly-silicon layer on the substrate; forming a gate insulator on the poly-silicon layer; forming a gate electrode; doping the poly-silicon layer with impurities around the gate electrode, the impurities comprising nitrogen, nitrogen being implanted to a depth no greater than that of other elements; and annealing the thin film transistor to activate and spread the implanting impurities and then form a lightly doped drain. The step of forming the poly-silicon layer comprises steps of: growing an amorphous silicon layer on the transparent substrate via chemical vapor deposition; transforming the amorphous silicon layer into the poly-silicon layer via hot processing; de-hydrogenating the poly-silicon layer and etching the poly-silicon layer so as to leave a pattern for use as a thin film transistor.

The step of doping the poly-silicon layer is conducted via ion implantation or ion shower. Nitrogen is implanted before or after other types of dope. Nitrogen is in the form of N₂⁺ or N⁺. The p-type of dope comprises at least one of boron and BF₂. The n-type of dope comprises at least one of phosphor and arsenic. Nitrogen is implanted with a dose of 1E13 ion/cm² or more. All of the types of dope are spread in a halo-like manner after the step of annealing. The step of annealing is conducted by means of a high-temperature stove or a rapid heating process.

Other objects, advantages and novel features of the present invention will become more apparent from the following detailed description referring to the attached drawings.

### BRIEF DESCRIPTION OF THE DRAWINGS

The present invention will be described via detailed illustration of embodiments referring to the drawings.

FIG. 1a and 1b show a conventional method for making a lightly doped drain of a low-temperature poly-crystal thin film transistor;

FIG. 2a to 2c are side views for showing a method for making a lightly doped drain of a low-temperature poly-crystal thin film transistor;

FIG. 3a is scheme for showing how nitrogen and other types of dope are spread in a poly-silicon layer; and

FIG. 3b is side view of a lightly doped drain of a low-temperature poly-crystal thin film transistor made according to the method of the present invention.

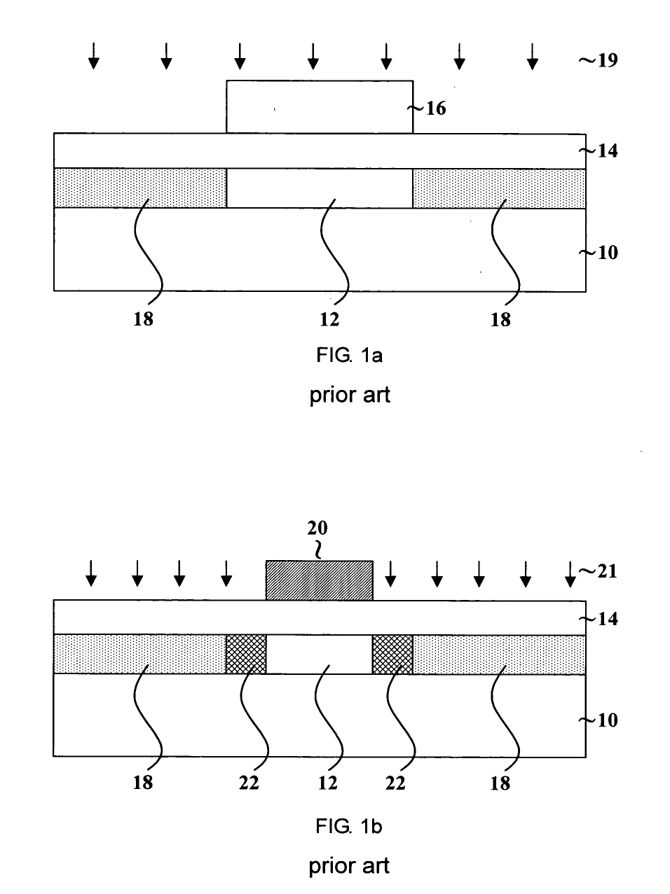

### DETAILED DESCRIPTION OF PREFERRED OF EMODIMENT

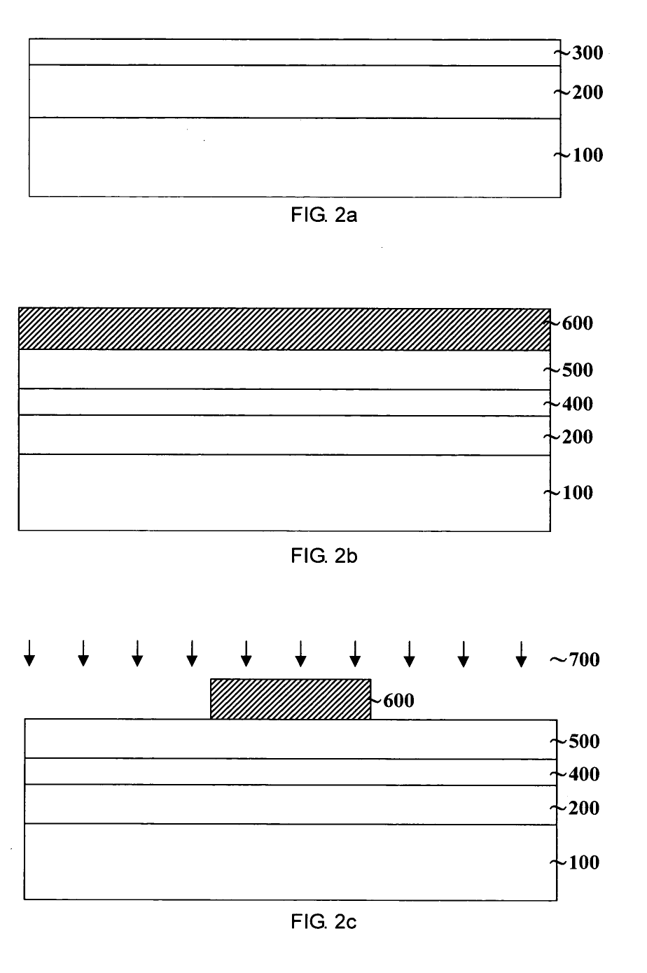

Referring to FIG. 2a to 2c, a method for producing a lightly doped drain structure according to the preferred embodiment of the present invention is shown. Referring to FIG. 2a, a washed glass substrate 100 is coated with a dielectric layer 200 through growing silica, silicon-nitride, or other proper insulating material on the glass substrate 100 by means of chemical vapor deposition (“CVD”). An amorphous silicon layer 300 is deposited on the dielectric layer 200. After hydrogenised, the amorphous silicon layer 300 is transformed into a poly-silicon layer 400 via laser or high-temperature annealing. The poly-silicon layer 400 is used as a channel for TFT. Redundant portions of the poly-silicon layer 400 are removed via etching. The intensity of the laser that can be used is in a range of 250 to 300 mJ/cm². The intensity of the laser that is used in the preferred embodiment is 260 mJ/cm².

Referring to FIG. 2b, on the poly-silicon layer 400 is grown SiO₂ or other proper dielectric material via CVD so as to form a gate insulator 500. A metal layer is formed on the gate insulator 500 via physical vapor deposition (“PVD”). The metal layer is etched so as to form a gate 600. The thickness of the gate insulator 500 is about 800 to 1000 angstroms. The thickness of the gate insulator 500 will affect the energy required for subsequent implanting of ions. Chrome, molybdenum, wolfram, tantalum, aluminum-rubidium alloy or any alloy thereof can be used to make the gate 600. When necessary, the gate 600 can include a multi-layer structure. To reduce resistance in wiring, it is necessary to increase the thickness of the metal layer properly. In the preferred embodiment, the thickness of the gate insulator 500 is 1000 angstroms. The thickness of the metal layer is 4000 angstroms.

Referring to FIG. 2c, the gate 600 is used as a mask for use in a doping operation where a portion of the poly-silicon layer 400 that is not covered by means of the gate 600 is doped with nitrogen (N₂⁺ or N⁺) and other dope 700. Doping is done via ion-implantation or ion shower. Compared with ion-shower, ion-implantation conducts tight control over the distribution of the numbers of the valence electrons of the ions. The implantation of the nitrogen takes place before the doping of the p-type dope (such as boron and BF₂) or the n-type dope (such as phosphor and arsenic) according to PMOS or NMOS. The doping of the p-type dope or the n-type dope may alternatively take place before the implantation of the nitrogen. However, it is preferred that the implantation of the nitrogen takes place before the doping of the p-type dope or the n-type dope.

As mentioned above, the energy required for the doping of the dope 700 is related to the thickness of the gate insulator 500. Where the thickness of the gate insulator 500 is 1000 angstroms, nitrogen is implanted with an energy level of 50 KeV and with a dose of 1E13/cm² to 2E15/cm², and boron is implanted with an energy level of 30 KeV and with a dose of 1E14/cm² to 5E15/cm², and phosphor is implanted with an energy level of 70 KeV with a dose of 1E14/cm² to 5E15/cm². The energy level for implanting nitrogen is determined so that nitrogen is implanted to a depth no greater than that of boron or phosphor. The dose of nitrogen is increased as the doses of the other types of dope are increased. A good profile can be achieved if the dose of nitrogen is higher than the doses of boron and phosphor. Where the doses of boron and phosphor are both 1E15/cm², a good profile is achieved if the dose of nitrogen is 2E15/cm², the spreading of the dope cannot be avoided adequately if the dose of nitrogen is 1E14/cm², and the spreading of the dope cannot be avoided at all if the dose of nitrogen is 1E13/cm².

After implanting nitrogen and the other types of dope, high-temperature annealing is conducted. Activated because of a high temperature, all types of dope are spread from a high-concentration area to a low-concentration area. The high-temperature annealing can be conducted by means of a high-temperature stove or rapid thermal processing (“RTP”). Where a high-temperature stove is used, it is operated at a temperature of 450° C. to 550° C. for a period of 2 to 4 hours. More particularly, the implantation of boron is conducted at 450° C. for 4 hours, and the implantation of phosphor is conducted at 550° C. for 4 hours. Where RTP is used, it is conducted at 550° C. to 650° C. for 10 seconds to 3 minutes. In the preferred embodiment, the implantations of boron and phosphor are both conducted at 600° C. for 1 minute.

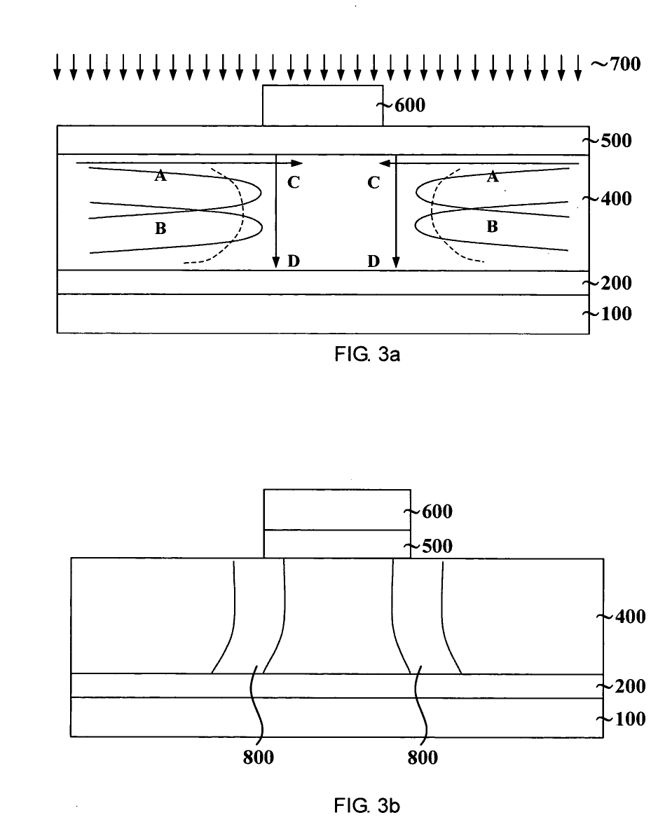

FIG. 3a shows the spreading of nitrogen and the other types of dope in the poly-silicon layer 400. An arrow C indicates the spreading takes place in a direction from the low-concentration area to the high-concentration area. An arrow D indicates a direction from a shallow area to a deep area. Since the ions are spread from the high-concentration area to the low-concentration area, and the portion of the poly-silicon layer 400 covered by means of the gate 600 without undergoing implantation is an area of the lowest concentration, the concentration gets lower from the portion of the poly-silicon layer 400 around the gate 600 to the portion of the poly-silicon layer 400 beneath the gate 600. When nitrogen ions of high concentration are implanted, it spreads at a high speed and repairs broken bonds of the poly-silicon layer 400 so as to turn them to a Si—N status. The distribution of nitrogen forms a barrier against boron and phosphor so as to slow down the spreading of boron and phosphor and to render their concentration distribution profile similar to that of nitrogen ions. Finally, a lightly doped drain 800 is formed referring to FIG. 3b. The gate insulator 500 has been etched. The portion of the poly-silicon layer 400 located between the lightly doped drains 800 and beneath the gate 600 is the channel. The portion of the poly-silicon layer 400 located beyond the lightly doped drains 800 is the drain or source area.

In the method for producing a lightly doped drain of a low-temperature poly-silicon thin film transistor, nitrogen is implanted during the steps of doping the source and the drain so as to suppress the spreading of the other types of dope so that all of the types of dope spread in the low-temperature poly-silicon in a halo-like manner so as to form a lightly doped drain that reduces the hot carrier effect. The steps of defining the source/drain are saved so as to avoid bias in alignment during exposure processes. Moreover, because the poly-silicon is repaired during the spreading nitrogen, the stability of the resultant transistor is improved.

The present invention has been described via detailed illustration of some embodiments. Those skilled in the art can derive variations from the embodiments without departing from the scope of the present invention. Therefore, the embodiments shall not limit the scope of the present invention defined in the claims.

What is claimed is

1. A method for producing a lightly doped drain of a low-temperature poly-crystal thin film transistor, the method comprising steps of:
providing a transparent substrate comprising a poly-silicon layer on said substrate and a gate insulator on said poly-silicon layer;
forming a metal film on said gate insulator;
doping said poly-silicon layer with impurities, said impurities comprising nitrogen and one selected from the p-type of dope and n-type of dope, nitrogen being implanted to a depth no greater than that of said p-type and said n-type of dope; and
annealing said thin film transistor to activate and spread the implanting impurities and then form a lightly doped drain.

2. The method according to claim 1 wherein said poly-silicon layer is formed in the steps of:
growing an amorphous silicon layer on said transparent substrate;
transforming said amorphous silicon layer into said poly-silicon layer via hot processing; and
etching said poly-silicon layer so as to leave a pattern for use as a thin film transistor.

3. The method according to claim 2 comprising, before said growing, a step of growing a dielectric layer on said transparent substrate by means of chemical vapor deposition.

4. The method according to claim 2 wherein said heating process is one of laser or high-temperature annealing.

5. The method according to claim 2 further comprising, between said transforming and said etching, a step of de-hydrogenation.

6. The method according to claim 1 wherein said gate insulator is formed via chemical vapor deposition.

7. The method according to claim 1 wherein said metal film is formed via physical vapor deposition.

8. The method according to claim 1 wherein said metal film comprises at least one of chrome, molybdenum, wolfram, tantalum, and aluminum-rubidium alloy.

9. The method according to claim 1 wherein said doping comprises a step of ion implantation.

10. The method according to claim 1 wherein said doping comprises a step of ion shower.

11. The method according to claim 1 wherein said nitrogen is implanted before the p-type of dope and the n-type of dope.

12. The method according to claim 1 wherein said p-type of dope and the n-type of dope is implanted before nitrogen.

13. The method according to claim 1 wherein said nitrogen is in the form of N₂⁺.

14. The method according to claim 1 wherein said nitrogen is in the form of N⁺.

15. The method according to claim 1 wherein said nitrogen is implanted with a dose of 1E13/cm².

16. The method according to claim 1 wherein said p-type of dope comprises at least one of boron and BF₂.

17. The method according to claim 1 wherein said n-type of dope comprises at least one of phosphor and arsenic.

18. The method according to claim 1 wherein said annealing is conducted at a temperature of 450° C. to 550° C. for a period of 2 to 4 hours.

19. The method according to claim wherein said annealing is conducted at a temperature of 550° C. to 650° C. for a period of 10 seconds to 3 minutes.
